(19) United States
(12) Patent Application Publication
(10) Pub. No.: US 2023/0131724 A1
(43) Pub. Date: Apr. 27, 2023

(54) METHOD AND DEVICE FOR IMPROVING ELEVATOR MAINTAINABILITY

(71) Applicants: Jiwu SUN, DONGGUAN (CN); Dongguan Yaosheng Auto Parts Co., Ltd., Dongguan (CN)

(72) Inventors: Junwei LIANG, DONGGUAN (CN); Jiwu SUN, DONGGUAN (CN)

(21) Appl. No.: 17/535,652

(22) Filed: Nov. 25, 2021

(30) Foreign Application Priority Data
Oct. 26, 2021 (CN) 202111251595.4

(51) Int. Cl. B66B 5/00; G01R 19/25; B66B 1/34

(52) U.S. Cl. CPC B66B 5/0037; G01R 19/2513; B66B 1/3476; B66B 5/0018

(57) ABSTRACT

The invention relates to a method and a device for improving elevator maintainability, comprising: selecting an efficient point; performing technical measurement to obtain a load−current changing curve and a current−time changing curve of the car; evaluating a mean value of the curve; generating a threshold; and counting to generate an inevitable remaining life Δt₂₁, wherein Δt₂₁=t₂−t₁. The inevitable remaining life Δt₂₁ is determined by the abnormal time threshold t₁ and the defect time threshold t₂, and is only related to the load−current changing curve and the current−time changing curve of the car, so that a user is capable of directly predicting the inevitable remaining life of the elevator, which presents excessive or missing maintenance, saves a maintenance industry, and belongs to the category of original intelligence.

### CROSS-REFERENCE TO RELATED APPLICATIONS

The present application claims foreign priority of Chinese Patent Application No. 202111251595.4, filed on Oct. 26, 2021 in the China National Intellectual Property Administration, the disclosures of all of which are hereby incorporated by reference.

### TECHNICAL FIELD

The present invention relates to a method and a device for improving elevator maintainability, and, more particularly, to a method and a device for improving elevator maintainability by recognizing an inevitable remaining life and saving a maintenance industry.

### BACKGROUND

At present, the installation and usage of elevators in China have been in the forefront of the world. As the safety and reliability of elevators are directly related to the life and property safety of users, elevator accidents have a great social impact. With the progress of technologies, an electrical system of the elevator has a certain self-checking function. When an elevator system failure is detected, the elevator will automatically stop running to ensure safety. The daily maintenance of the elevator is regularly completed by manual inspection in general. Professional maintenance personnel are responsible for the maintenance after the elevator system failure. However, the above methods cannot fundamentally save the maintenance industry

For example, Chinese Patent No. CN201110075298.9 discloses a method for elevator control reminding and fault self-diagnosis and a system thereof. This patent does not take materials, energy and information of elevator driving units, i.e., does not take control and communication within or between organizations as research objects, so it is impossible to know the inevitable remaining life and save the maintenance industry in essence. Such excessive or missing maintenance and repairing will either cause great waste or bring potential safety hazards.

### SUMMARY

An object of the present invention is to provide a method and a device for improving elevator maintainability, so as to solve the technical problems in the related art that the inevitable remaining life cannot be recognized and the maintenance industry cannot be saved. Technical solutions adopted by the present invention to solve the technical problems thereof are as follows.

A method for improving elevator maintainability, comprises:

step S100: selecting efficient points, selecting a measurement point of a car load sample as an efficient point and selecting a measurement point of a drive current sample as an efficient point;

step S200: performing technical measurement, statistically measuring a car load sample value qhi and a drive current sample value Iᵢ in step S100 to obtain a load−current changing curve and a current−time changing curve of the car;

step S300: evaluating a mean value of the curve, and evaluating a mean valueμ(μₜ, μ_{t-kσt}, μ_{I+kσI}, μ_{I}) of fitting equations of the curve:

μ_{t-kσt}=·|k_{counterweight}·qh−qhᵢ|+B, [equation 1]

μ_{I+kσI}=b·|k_{counterweight}·qh−qhᵢ|+C, [equation 2]

μₜ=b·|k_{counterweight}·qh−qhᵢ|+A, [equation 3]

μ_{I}=b·|k_{counterweight}·qh−qhᵢ|+D; [equation 4]

wherein b is a slope of the equation, k_{counterweight} is a counterbalancing coefficient of an elevator, qh is a rated load, and A, B, C and D represent longitudinal axis intercepts of the equations 1, 2, 3 and 4 respectively;

step S400: generating a threshold, and generating the threshold according to the measurement results in step S200, comprising:

step S401: generating an abnormal time threshold t₁;

step S402: generating a defect time threshold t₂; and,

step S500: judging whether a time of the equation 2 in step S300 is greater than t₁, and judging whether a time of the equation 1 in step S300 is greater than t₂; and

if a certain time in the equation 2 is greater than t₁ and a certain time in the equation 1 is greater than t₂,

counting to generate an inevitable remaining life Δt₂₁, wherein

Δt₂₁=t₂−t₁. [equation5]

Further, in step S401, a judgment standard of the abnormal time is that: if a current capacity passing through the car load sample at a certain time exceeds an allowable current capacity, then the time is the abnormal time.

Further, influencing factors of the mean value μ of the load−current changing curve and the current−time changing curve of the car are derived from a nominal element, an actual element, an extracted element, a fitted element and a fitted+element.

Further, in step S401, the generating the abnormal time threshold specifically comprises the following steps of:

abstracting the equation 1 and nominal elements (μ_{I}, +k94 _{I}) and (μₜ, −kσₜ);
measuring an actual element ±kσᵢ;
extracting the element (μ_{I}, +kσ_{I});
fitting the element (μₜ, +kσₜ); and
generating the abnormal time threshold t₁, wherein t₁=|μ_{I}±kσ_{I}|;

in the above step, k represents a coefficient of a standard deviation of normal distribution (a relationship between a sigma level and defects per million opportunity) of the load−current changing curve and the current−time changing curve of the car, and at represents a variance of the load−current and the current−time changing curve of the car.

Further, a value range of k is 1 to 6.

Further, the car load sample is obtained through a cloud-interface loadmeter of the car, and the drive current sample is through a cloud-interface clip-on ammeter.

The present invention further provides to a device for improving elevator maintainability, comprising:
a car load sample configured for providing car load information;
a drive current sample at least comprising an input current detection module and an output current detection module, wherein the input current detection module is configured for detecting an input current of the car load sample and the output current detection module is used for detecting an output current of the car load sample;
a central processing unit respectively connected with the car load sample and the drive current sample; and
a sensor configured for feeding back an input current detected by the input current detection module to the central processing unit.

Further, the car load sample is obtained through a cloud-interface loadmeter of the car, and the drive current sample is through a cloud-interface clip-on ammeter.

According to one of the technical solutions of the present invention, the load−current changing curve and the current−time changing curve of the car are obtained by statistically measuring the car load sample value qhi and the drive current sample value Iᵢ, and the inevitable remaining life Δt₂₁ of the elevator is generated by evaluating the mean value of the curve and comparing the mean value with the abnormal time threshold value t₁ and the defect time threshold value t₂. Because the inevitable remaining life Δt₂₁ is determined by the abnormal time threshold t₁ and the defect time threshold t₂, and is related to the load−current changing curve and the current−time changing curve of the car, a user can directly predict the inevitable remaining life of the elevator. This is an active maintenance method, which can save the maintenance industry and prevent adverse consequences caused by excessive or missing maintenance and repair, without paying attention to the operation of the elevator in real time.

According to the second technical solution of the present invention, the present invention belongs to the category of original intelligence (abbreviated as OI), which processes the load−current changing curve and the current−time changing curve of the car through the central processing unit, and carries out statistics and “big data” statistical measurement on the car load sample value qhᵢ, the drive current sample value Ii and the inevitable remaining life sample Δt₂₁, abandoning post-event, planned and spot-like “uncertainty” maintenance. The device of the present invention has simple structure, and the detection method is convenient and effective, which better improves the elevator maintainability and improves the user's experience.

### BRIEF DESCRIPTION OF THE DRAWINGS

FIG. 1 is a flowchart of a method for improving elevator maintainability according to one embodiment of the present invention;

FIG. 2 is a schematic diagram of a nominal element in the method for improving the elevator maintainability according to one embodiment of the present invention;

FIG. 3 is a schematic diagram of an actual element in the method for improving the elevator maintainability according to one embodiment of the present invention;

FIG. 4 is a schematic diagram of an extracted element in the method for improving the elevator maintainability according to one embodiment of the present invention;

FIG. 5 is a schematic diagram of a fitted element in the method for improving the elevator maintainability according to one embodiment of the present invention;

FIG. 6 is a schematic diagram of a fitted+element in the method for improving the elevator maintainability according to one embodiment of the present invention; and

FIG. 7 is a structural block diagram of a device for improving elevator maintainability according to one embodiment of the present invention.

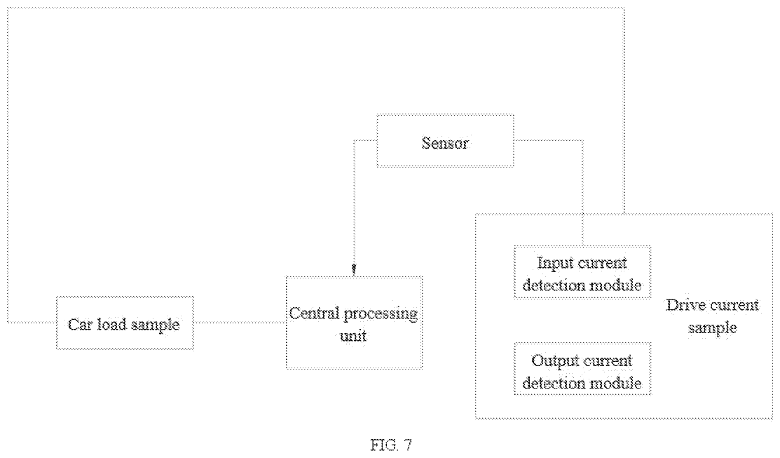

### DETAILED DESCRIPTION

In order to make the above objects, features and advantages of the present invention be more clearly understood, the specific embodiments of the present invention will be described in further detail below with reference to the drawings. In the following description, numerous specific details are set forth in order to fully understand the present invention. However, the present invention can be implemented in many other ways different from those described herein, and those skilled in the art can make similar improvements without violating the connotation of the present invention, so the present invention is not limited by the specific embodiments disclosed below.

In the description of the present invention, it should be understood that the orientations or positional relationships indicated by the terms such as “center”, “longitudinal”, “horizontal”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential” and the like, refer to the orientations or positional relationships based on the accompanying drawings, which are only intended to facilitate describing the present invention and simplifying the description, and do not indicate or imply that the indicated devices or elements must have a specific orientation, be constructed and operated in a specific orientation, and therefore cannot be understood as a limitation of the present invention.

Moreover, the terms “first” and “second” are only used for descriptive purposes, but cannot be understood as indicating or implying relative importance, or implicitly indicating the number of indicated technical features. Therefore, the features defined with “first” and “second” can explicitly or implicitly comprise at least one of the features. In the description of the present invention, the meaning of “multiple” is two or more than two, such as two, three, and the like, unless otherwise specifically defined.

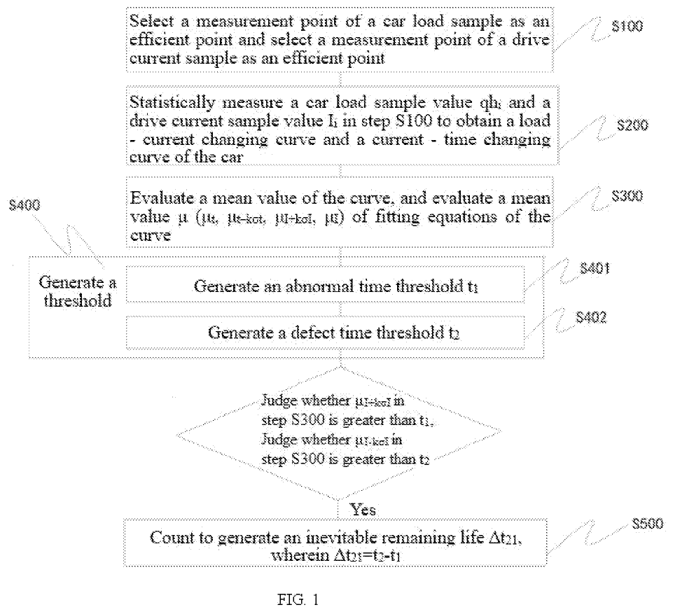

Referring to FIG. 1 to FIG. 6, the present invention provides a method for improving elevator maintainability, comprising:

step S100: selecting efficient points, selecting a measurement point of a car load sample as an efficient point and selecting a measurement point of a drive current sample as an efficient point;

step S200: performing technical measurement, statistically measuring a car load sample value qhi and a drive current sample value Iᵢ in step S100 to obtain a load−current changing curve and a current−time changing curve of the car;

step S300: evaluating a mean value of the curve, and evaluating a mean valueμ(μₜ, μ_{t-kσt}, μ_{I+kσI}, μ_{I}) of fitting equations of the curve:

μ_{t-kσt}=b·|k_{counterweight}·qh−qhᵢ|+B, [equation 1]

μ_{I+kσI}=b·|k_{counterweight}·qh−qhᵢ|+C, [equation 2]

μₜ=b·|k_{counterweight}·qh−qhᵢ+|A, [equation 3]

μ_{I}=b·|k_{counterweight}·qh−qhᵢ|+D; [equation 4]

wherein b is a slope of the equation, k_{counterweight} is a counterbalancing coefficient of an elevator, qh is a rated load, and A, B, C and D represent longitudinal axis intercepts of the equations 1, 2, 3 and 4 respectively;

step S400: generating a threshold, and generating the threshold according to the measurement results in step S200, comprising:

step S401: generating an abnormal time threshold t₁;

step S402: generating a defect time threshold t₂; and,

step S500: judging whether a time of the equation 2 in step S300 is greater than t₁, and judging whether a time of the equation 1 in step S300 is greater than t₂;

if a certain time in the equation 2 is greater than t₁ and a certain time in the equation 1 is greater than t₂,

counting to generate an inevitable remaining life Δt₂₁, wherein

Δt₂₁=t₂−t₁. [equation 5]

According to the present invention, the load−current changing curve and the current−time changing curve of the car are obtained by statistically measuring the car load sample value qhᵢ and the drive current sample value Iᵢ, and the inevitable remaining life Δt₂₁ of the elevator is generated by evaluating the mean value of the curve and comparing the mean value with the abnormal time threshold value t₁ and the defect time threshold value t₂. Because the inevitable remaining life Δt₂₁ is determined by the abnormal time threshold t₁ and the defect time threshold t₂, and is related to the load−current changing curve and the current−time changing curve of the car, a user can directly predict the inevitable remaining life of the elevator. This is an active maintenance method, which can save the maintenance industry and prevent adverse consequences caused by excessive or missing maintenance and repair, without paying attention to the operation of the elevator in real time.

In step S401, a judgment standard of the abnormal time is that: if a current capacity passing through the car load sample at a certain time exceeds an allowable current capacity, then the time is the abnormal time.

In the present invention, influencing factors of the mean value μ of the current−time changing curve of the car load sample are derived from a nominal element, an actual element, an extracted element, a fitted element and a fitted+element. In step S401, the generating the abnormal time threshold specifically comprises the following steps of: abstracting the equation 1 and nominal elements (μ_{I}, +kσ_{I}) and (μₜ, −kσₜ), measuring an actual element extracting the element (μ, +kσ_{I}) fitting the element (μₜ, +kσₜ), and finally generating the abnormal time threshold t₁, wherein t₁=|μ_{I}±kσ_{I}|. In the above step, k represents a coefficient of a standard deviation of normal distribution (a relationship between a sigma level and defects per million opportunity) of the load−current changing curve and the current−time changing curve of the car, σ_{I} represents a variance of the load−current changing curve and the current−time changing curve of the car, and a value range of k is 1 to 6.

In this embodiment, the car load sample is obtained through a cloud-interface loadmeter of the car, and the drive current sample is through a cloud-interface clip-on ammeter. This embodiment provides to a device for improving elevator maintainability, comprising: a car load sample, which may be configured for providing car load information; a drive current sample at least comprising an input current detection module and an output current detection module, wherein the input current detection module is configured for detecting an input current of the car load sample and the output current detection module is used for detecting an output current of the car load sample; a central processing unit respectively connected with the car load sample and the drive current sample; and a sensor configured for feeding back an input current detected by the input current detection module to the central processing unit. The present invention belongs to the category of original intelligence (abbreviated as (OI), which processes the load−current changing curve and the current−time changing curve of the car through the central processing unit, and carries out statistics and “big data” statistical measurement on the car load sample value qhᵢ, the drive current sample value Ii and the inevitable remaining life sample Δt₂₁, abandoning post-event, planned and spot-like “uncertainty” maintenance. The device of the present invention has simple structure, and the detection method is convenient and effective, which better improves the elevator maintainability and improves the user's experience.

An elevator of an enterprise apartment in Dongguan, Guangdong Province was taken as a research object. See Table 1 for some specific parameters of the elevator:

TABLE 1
Some parameters such as elevator nameplate of an enterprise
apartment in Dongguan, Guangdong Province

| Rated | 1.5 | m/s | Rated | 1,000 | kg | Rated | 665 | Nm |
|---|---|---|---|---|---|---|---|---|
| speed | | | load | | | torque | | |
| Model | WYT-T | | Pulley | 400 | mm | Factory | H1950078 | |
| Rated | 380 | V | diameter | | | number | | |
| voltage | | | Rated | 22.2 | A | Rated | 10 | kw |
| Rated | 24 | Hz | current | | | power | | |
| frequency | | | Rated | 144 | r/min | Axle load | 3,500 | kg |

rotating
speed

| | | |
|---|---|---|
| Random load | Counterweight | Driving force |
| of car qhᵢ | coefficient0.45 | \|45kg-qhᵢ\| |

| | |
|---|---|
| Weight percentage of | Transmission efficiency η |
| counterweight: 45 | ranges from 1.05 to 1.20 |

A method for improving elevator maintainability in this embodiment was approximately as follows.

1. Efficient Points were Selected

A random sample measuring point of a cloud−interface loadmeter of the car was selected as an efficient point, and a random driving sample metering point of a cloud−interface clip-on ammeter was selected as an efficient point.

### 2. Technical Measurement was Performed.

A load random sample value qhᵢ of the cloud-interface loadmeter of the car was statistically measured. See Table 2 for the detailed values. A random drive sample value Iᵢ of the cloud-interface clip-on ammeter was statistically measured. See Table 2 for the detailed values.

TABLE 2
Statistical table of drive current Iᵢ and load sample qhᵢ
Downlink

| | | Weight: | | | Weight: | | | Weight: | | | Weight: | |
|---|---|---|---|---|---|---|---|---|---|---|---|---|
| Serial | Number | 0 | Mean | Number | 79.5 | Mean | Number | 135 | Mean | Number | 190 | Mean |
| number | of sets | Current | value | of sets | Current | value | of sets | Current | value | of sets | Current | value |
| 1 | 1 | 17.03 | 16.09 | 2 | 13.62 | 13.62 | 3 | 12.92 | 12.09 | 4 | 10.99 | 10.36 |
| 2 | | 16.55 | | | 14.27 | | | 12.58 | | | 10.99 | |
| 3 | | 15.57 | | | 13.54 | | | 11.66 | | | 9.88 | |
| 4 | | 15.21 | | | 13.05 | | | 11.19 | | | 9.58 | |

Downlink

| | | Weight: | | | Weight: | | | Weight: | |
|---|---|---|---|---|---|---|---|---|---|
| Serial | Number | 255 | Mean | Number | 325 | Mean | Number | 400 | Mean |
| number | of sets | Current | value | of sets | Current | value | of sets | Current | value |
| 1 | 5 | 8.73 | 8.73 | 6 | 7.47 | 6.72 | 7 | 4.87 | 4.17 |
| 2 | | 9.41 | | | 7.42 | | | 4.84 | |
| 3 | | 8.69 | | | 6.50 | | | 3.68 | |
| 4 | | 8.09 | | | 5.52 | | | 3.27 | |

Uplink

| | | Weight: | | | Weight: | | | Weight: | | | Weight: | |
|---|---|---|---|---|---|---|---|---|---|---|---|---|
| Serial | Number | 470 | Mean | Number | 535 | Mean | Number | 590 | Mean | Number | 645 | Mean |
| number | of sets | Current | value | of sets | Current | value | of sets | Current | value | of sets | Current | value |
| 1 | 8 | 4.77 | 3.67 | 9 | 6.28 | 5.26 | 10 | 7.74 | 6.97 | 11 | 8.35 | 8.35 |
| 2 | | 3.93 | | | 5.72 | | | 7.40 | | | 8.72 | |
| 3 | | 3.21 | | | 4.93 | | | 6.73 | | | 8.38 | |
| 4 | | 2.82 | | | 4.12 | | | 6.02 | | | 7.96 | |

Uplink

| | | Weight: | | | Weight: | | | Weight: | |
|---|---|---|---|---|---|---|---|---|---|
| Serial | Number | 725 | Mean | Number | 0 | Mean | Number | 820.5 | Mean |
| number | of sets | Current | value | of sets | Current | value | of sets | Current | value |
| 1 | 12 | 11.90 | 10.79 | 13 | 17.03 | 16.09 | 14 | 13.62 | 13.62 |
| 2 | | 10.91 | | | 16.55 | | | 14.27 | |
| 3 | | 10.37 | | | 15.57 | | | 13.54 | |
| 4 | | 10.01 | | | 15.21 | | | 13.05 | |

The car load sample value qhi and the drive current sample value Iᵢ in Table 2 were statistically measured to obtain a load−current changing curve and a current−time changing curve of the car;

A mean value μ(μₜ, μ_{t-kσt}, μ_{I+kσI}, μ_{I}) of fitting equations of the curve was evaluated:

μ_{t-kσt}=b·|k_{counterweight}·qh−qhᵢ|+B, [equation 1]

ρ_{I+kσI}=b·|k_{counterweight}·qh−qhᵢ|+C, [equation 2]

μₜ=b·|k_{counterweight}·qh−qhᵢ|+A, [equation 3]

μ_{I}=b·|k_{counterweight}·qh−qhᵢ|+D; [equation 4]

wherein b was a slope of the equation, k_{counterweight} was a counterbalancing coefficient of an elevator, qh was a rated load, and A, B, C and D represented longitudinal axis intercepts of the equations 1, 2, 3 and 4 respectively;

When the equation [equation 2] exceeded the threshold |μ_{I+kσI}|, it was judged as an abnormal time t₁;

when the equation [equation 1] fell within the threshold |μ_{t-kσt}|, it was judged as a defect time t₂; and

an inevitable remaining life Δt₂₁ was obtained, wherein Δt₂₁=t₂−t₁.

It can be illustrated more vividly by the following figures:
------A------
------B------
------C------
------D------

generating a threshold:

BC=AD−AB−AC=μ_{I}μₜ−(−kσₜμₜ+kσ_{I}μ_{I})
solving μₜ, σₜ and μ_{I}, σ_{I}
making a judgment:
when t₁>C, it was the abnormal time t₁; and
when t₂>B, it was the defect time t₂.

The inevitable remaining life was obtained:

BC=AD−AB−CD=μ_{I}μₜ−(−kσₜμₜ+kσ_{I}μ_{I}0=4.7 days

3. A threshold was generated.

### Intercept Cᵢ:

A nominal element μ_{I} equation was abstracted: μ_{I}=b·|k_{counterweight}·qh−qhᵢ|+Cᵢ

wherein b=k Σ·/U (obtained according to actual elements and least square geometric method)

wherein, k_{Σ1}=k_{D}vη_{Σ}g;

kD was a motor safety factor, V was a rated speed, ηΣ was a total transmission efficiency, g was a gravity acceleration, and U was a rated voltage of peak-valley power during valley power period.

k_{counterweight}·qh represented a lifting force. When k_{counterweight} ·qh−qhi>0, the lifting force on a driving wheel was counterclockwise; when k_{counterweight}·qh−qhi<0, the lifting force on the driving wheel was clockwise.

wherein, k_{counterweight} was a counterbalancing coefficient, qh was a rated load, and Cᵢ was a Σ longitudinal intercept (coefficient influenced by other factors, obtained by the least square geometric method).

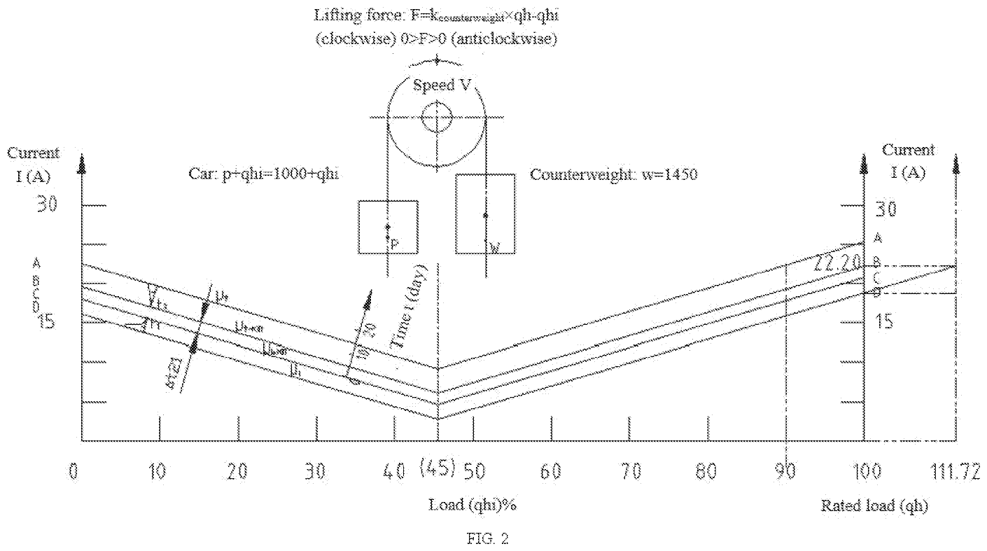

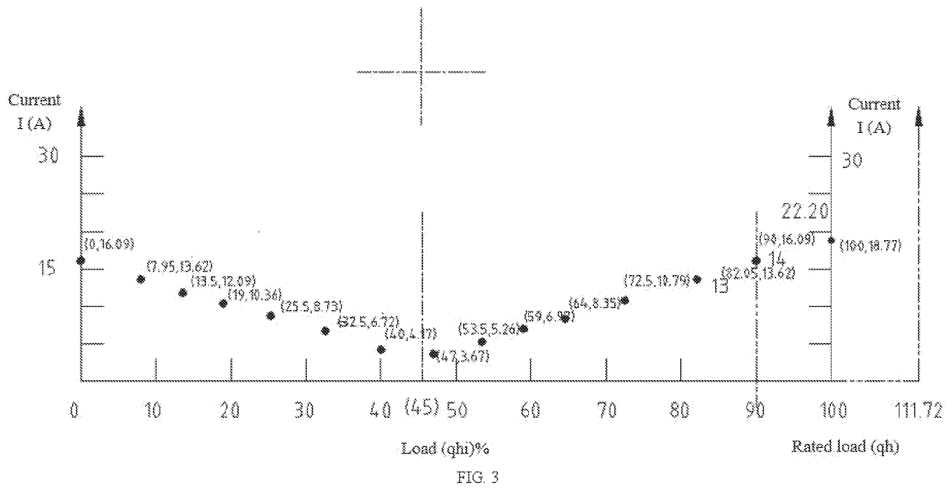

3.1 A nominal component element ±kσ₁ and a nominal derived c element μ_{I} were abstracted. See FIG. 2 and Table 3 for details.
μ_{I actual}—as shown in FIG. 3
μ_{I nominal}—as shown in FIG. 2

TABLE 3
Difference table between actual element μ_{I actual} and nominal element μ_{I nominal}
in this embodiment, there were total 56 samples 4* 14 (serial number).

| | μ_{I actual} | | μ_{I nominal} = 0.296(45-qhi) + 2.77 | | μ_{I actual} · μ_{I nominal} |
|---|---|---|---|---|---|
| Serial | k_{counterweight} · | | k_{counterweight} · | | μ_{I experimental} · |
| number | qh-qhᵢ | μ_{I experimental} | qh-qhᵢ | μ_{I theoretical} | μ_{I theoretical} |
| 1 | 45.00 | 16.09 | 45.00 | 16.09 | 00.00 |
| 2 | 37.05 | 13.62 | 37.05 | 13.74 | −0.12 |
| 3 | 32.50 | 12.09 | 32.50 | 11.74 | −0.35 |
| 4 | 26.00 | 10.36 | 26.00 | 10.47 | −0.11 |
| 5 | 19.50 | 08.73 | 19.50 | 08.54 | 00.19 |
| 6 | 12.50 | 06.72 | 12.50 | 06.47 | 00.25 |
| 7 | 05.00 | 04.17 | 05.00 | 04.25 | −0.08 |
| 8 | 02.00 | 03.67 | 02.00 | 02.18 | 01.49 |
| 9 | 08.50 | 05.26 | 08.50 | 05.29 | −0.03 |
| 10 | 14.00 | 06.97 | 14.00 | 06.91 | 00.06 |
| 11 | 19.50 | 08.35 | 19.50 | 08.39 | −0.04 |
| 12 | 27.50 | 10.79 | 27.50 | 10.91 | −0.12 |
| 13 | 37.05 | 13.62 | 37.05 | 13.74 | −0.12 |
| 14 | 45.00 | 16.09 | 45.00 | 16.09 | 00.00 |

3.2 The actual element ±k_{σI} was measured, as shown in FIG. 3.

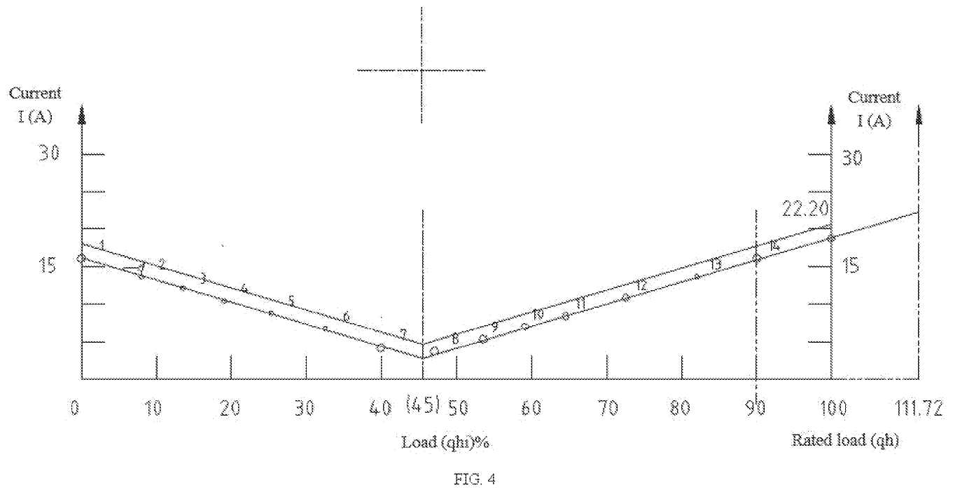

3.3 Elements (μ_{I}, +kσ_{I}) were extracted, and the derived element μ_{I} was extracted, as shown in FIG. 4.

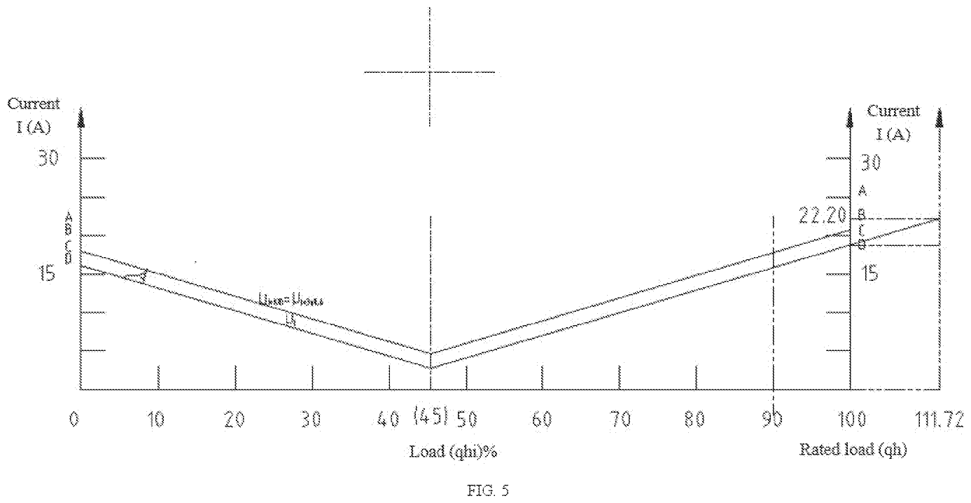

3.4 Elements (μₜ, +kσₜ) were fitted, and the derived element μ_{I} was fitted to generate an abnormal time (t₁ specification|μ_{I}±kσ_{I}|) threshold. See FIG. 5 and Table 4 for details.

TABLE 4
Difference table between actual element
(μ_{I actual} and nominal element μ_{I nominal}

| Weight | Serial number | Nominal | Actual | Difference |
|---|---|---|---|---|
| 45 | 1 | 17.03 | 16.09 | 0.94 |
| | 2 | 16.55 | 16.09 | 0.46 |
| | 3 | 15.57 | 16.09 | −0.52 |
| | 4 | 15.21 | 16.09 | −0.88 |
| 37.05 | 5 | 13.62 | 13.74 | −0.12 |
| | 6 | 14.27 | 13.74 | 0.53 |
| | 7 | 13.54 | 13.74 | −0.2 |
| | 8 | 13.05 | 13.74 | −0.69 |
| 32.5 | 9 | 12.92 | 11.74 | 1.18 |
| | 10 | 12.58 | 11.74 | 0.84 |
| | 11 | 11.66 | 11.74 | −0.08 |
| | 12 | 11.19 | 11.74 | −0.55 |
| 26 | 13 | 10.99 | 10.47 | 0.52 |
| | 14 | 10.99 | 10.47 | 0.52 |
| | 15 | 9.88 | 10.47 | −0.59 |
| | 16 | 9.58 | 10.47 | −0.89 |
| 19.5 | 17 | 8.73 | 8.54 | 0.19 |
| | 18 | 9.41 | 8.54 | 0.87 |
| | 19 | 8.69 | 8.54 | 0.15 |
| | 20 | 8.09 | 8.54 | −0.45 |
| 12.5 | 21 | 7.47 | 6.47 | 1 |
| | 22 | 7.42 | 6.47 | 0.95 |
| | 23 | 6.50 | 6.47 | 0.03 |
| | 24 | 5.52 | 6.47 | −0.95 |
| 5 | 25 | 4.87 | 4.25 | 0.62 |
| | 26 | 4.84 | 4.25 | 0.59 |
| | 27 | 3.68 | 4.25 | −0.57 |
| | 28 | 3.27 | 4.25 | −0.98 |
| 2 | 29 | 4.77 | 2.18 | 2.59 |
| | 30 | 3.93 | 2.18 | 1.75 |
| | 31 | 3.21 | 2.18 | 1.03 |
| | 32 | 2.82 | 2.18 | 0.64 |
| 8.5 | 33 | 6.28 | 5.29 | 0.99 |
| | 34 | 5.72 | 5.29 | 0.43 |
| | 35 | 4.93 | 5.29 | −0.36 |
| | 36 | 4.12 | 5.29 | −1.17 |
| 14 | 37 | 7.74 | 6.91 | 0.83 |
| | 38 | 7.40 | 6.91 | 0.49 |
| | 39 | 6.73 | 6.91 | −0.18 |
| | 40 | 6.02 | 6.91 | −0.89 |
| 19 | 41 | 8.35 | 8.39 | −0.04 |
| | 42 | 8.72 | 8.39 | 0.33 |
| | 43 | 8.38 | 8.39 | −0.01 |
| | 44 | 7.96 | 8.39 | −0.43 |
| 27.5 | 45 | 11.90 | 10.91 | 0.99 |
| | 46 | 10.91 | 10.91 | 0 |
| | 47 | 10.37 | 10.91 | −0.54 |
| | 48 | 10.01 | 10.91 | −0.9 |
| 45 | 49 | 17.03 | 16.09 | 0.94 |
| | 50 | 16.55 | 16.09 | 0.46 |
| | 51 | 15.57 | 16.09 | −0.52 |
| | 52 | 15.21 | 16.09 | −0.88 |
| 37.05 | 53 | 13.62 | 13.74 | −0.12 |
| | 54 | 14.27 | 13.74 | 0.53 |
| | 55 | 13.54 | 13.74 | −0.2 |
| | 56 | 13.05 | 13.74 | −0.69 |

Considering b-tang and the samples in Table 4, it could be concluded that:

(1) Let a≈0, and σ_{I}=0.6466; and

(2) Let a=16.49° and μ_{I}=0.62. In this embodiment, (1) was employed and σ_{I}=0.6. Fitting: C_{I}=2.77, as shown in FIG. 5, it could be obtained from nominal equation 1 and fitting equation 2:

μ_{I}=0.296(45−qhᵢ)+2.77

The fitting derived element was μ_{I}, and the fitting component elements ±kσ_{I} were; ±3×0.6=±1.8, and |μₜ±1.8|, as shown in FIG. 5.

Similarly, the cu rent-time changing curve was obtained:

As shown in FIG. 5

TABLE 5
statistical table of sample of inevitable remaining life tₜ

| Serial number | Error: tₜ (day) |
|---|---|
| 1 | 19.8 |
| 2 | 19.0 |
| 3 | 05.6 |
| 4 | 21.4 |
| 5 | 12.8 |
| 6 | 08.0 |
| 7 | 23.0 |
| 8 | 14.4 |
| 9 | 16.8 |
| 10 | 17.4 |
| 11 | 12.0 |
| 12 | 07.2 |
| 13 | 13.6 |
| 14 | 09.6 |
| 15 | 15.2 |
| 16 | 16.0 |
| 17 | 11.2 |
| 18 | 10.4 |
| 19 | 18.2 |
| 20 | 28.6 |
| 21 | 04.0 |
| 22 | 20.6 |
| 23 | 06.4 |
| 24 | 22.2 |
| 25 | 08.8 |
| 26 | 23.8 |
| 27 | 04.8 |

Mean value: μₜ = [(23.8 + 4.8)/2]−4.8 = 9.5
σₜ = (tₜₘᵢₙ − tₜₘₐₓ)/±k = (23.8-4.8)/6 = 3.2

Note: extreme values or abnormal data was excluded, In. this case, the extreme values 20 and 21 were excluded.

A threshold was generated,

Intercept Cᵢ:

tₜ=μ_{I}+kσ_{I} [equation 5]

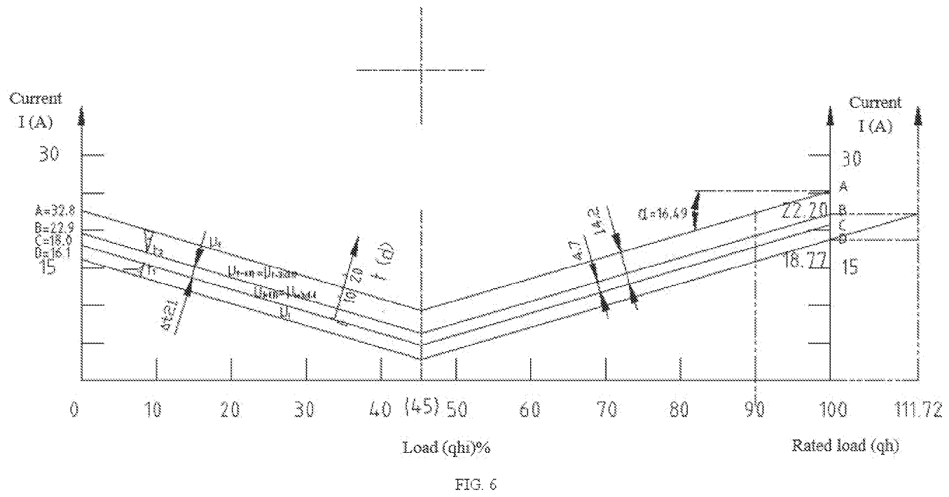

Equation [equation 5]=0, and 13,3+3*0.6=15.1. was an initial zero point of the abnormal time, referring to FIG. 6.

t_{I}=μₜ−kσₜ [equation 6]

Equation [equation 6]=(9.5+4.8)−3×3.2=4.7, which was an end point of the defect time, referring to FIG. 6. The threshold was between the abnormal time 0 and the detect time 4.7.

Judgments were made.

Intercept Cᵢ:

1. When equation [equation 5]=15.1, it was judged as the abnormal time zero t₁=0, as shown in FIG. 6.

2. When equation [equation 6] fell within the threshold of 4.7, it was judged as the defect time t₂−4.7, as shown in FIG.6.

3. The inevitable remaining life Δt₂₁ was obtained.

Intercept Cᵢ:

Δt₂₁=t₂−t₁
μ_{t-kσt}—t₁=(9.5+4.8)−3/3.2=4.7
μ_{I-kσI}—t₁=13.3+3×0.6=15.1 (t₁=15.1=0 was the initial point)
Δt₂₁=4.7 (day), referring to FIG. 6 for details.

### Block Legislation

In this case, a form of enterprise WeChat is employed it the front desk to solve a problem of decentralized distributed ledger at the front desk; and a bloekehain method is used in the background to solve a background block legislation problem.

### Remanufacturing

When a spare part is abnormal: the spare part needs to be either replaced or remanufactured.

The former: establishing a one-to-one correspondence with an elevator company, a network platform, a logistics company and a mobile communication company to keep the original remanufactured and replaced.

The latter: establishing a one-to-one correspondence with a remanufacturing factory, a network platform, a logistics company and a mobile communication company to keep the original remanufactured and replaced.

### Beneficial Effects

First of all, the inevitable remaining life of the elevator can be accurately understood, all operation and maintenance problems can be solved through a certain parameter to save the maintenance industry. This understanding and saving can not only avoid great waste, but also ensure the operation safety. Secondly, the ecological environment of non-green operation and maintenance in the industry is broken. Finally, a modest means is made to carbon peak reduction.

Carbon peak reduction refers to a brand-new green industrial revolution, the essence and characteristics of which are [original intelligence-OI (initiative)], which greatly improves the productivity of resources, completely decouples economic growth from non-renewable resources, and completely separates from greenhouse gas emissions such as carbon dioxide, and is twice the result with half the effort in comparison with peak carbon dioxide emissions and carbon neutrality.

The above embodiments merely express several embodiments of the present invention, the descriptions of which are more specific and detailed, but cannot be understood as limiting the scope of protection of the present invention. It should be noted that those of ordinary skills in the art may make a plurality of decorations and improvements without departing from the conception of the present invention, and these decorations and improvements shall all fall within the scope of protection of the present invention. Therefore, the scope of protection of the present invention shall be subjected to the claims appended.

1. A method for improving elevator maintainability, comprising the following steps of:
step S100: selecting efficient points, selecting a measurement point of a car load sample as an efficient point and selecting a measurement point of a drive current sample as an efficient point;
step S200: performing technical measurement, statistically measuring a car load sample value qhᵢ and a drive current sample value Iᵢ in step S100 to obtain a load−current changing curve and a current−time changing curve of the car;
step S300: evaluating a mean value of the curve, and evaluating a mean value μ(μₜ, μ_{t-kσt}, μ_{I+kσI}, μ_{I}) of fitting equations of the curve:
μ_{t-kσt}=b·|k_{counterweight}·qh−qhᵢ|+B, [equation 1]
μ_{I+kσI}=b·|k_{counterweight}·qh−qhᵢ|+C, [equation 2]
μₜ=b·|k_{counterweight}·qh−qhᵢ|+A, [equation 3]
μ_{I}=b·|k_{counterweight}·qh−qhᵢ|D; [equation 4]
wherein b is a slope of the equation, k_{counterweight} is a counterbalancing coefficient of an elevator, qh is a rated load, and A, B, C and D represent longitudinal axis intercepts of the equations 1, 2, 3 and 4 respectively;
step S400: generating a threshold, and generating the threshold according to the measurement results in step S200, comprising:
step S401: generating an abnormal time threshold t₁;
step S402: generating a defect time threshold t₂; and,
step S500: judging whether a time of the equation 2 in step S300 is greater than t₁, and judging whether a time of the equation 1 in step S300 is greater than t₂; and
if a certain time in the equation 2 is greater than t₁ and a certain time in the equation 1 is greater than t₂,
counting to generate an inevitable remaining life Δt₂₁, wherein
Δt₂₁=t₂−t₁, [equation 5]

2. The method according to claim 1, wherein in step S401, a judgment standard of the abnormal time is that: if a current capacity passing through the car load sample at a certain time exceeds an allowable current capacity, then the time is the abnormal time.

3. The method according to claim 1, wherein influencing factors of the mean value μ of the load−current changing curve and the current−time changing curve of the car are derived from a nominal element, an actual element, an extracted element, a fitted element and a fitted+element.

4. The method according to claim 1, wherein in step S401, the generating the abnormal time threshold specifically comprises the following steps of:
abstracting the equation 1 and nominal elements (μᵢ, +kσ_{I}) and (μₜ, −kσₜ);
measuring an actual element ±kσ_{I};
extracting the element (μ_{I}, +kσ_{I});
fitting the element (μₜ, +kσ_{I}); and
generating the abnormal time threshold t₁, wherein t₁=|μ_{I}±kσ_{I}|;
in the above step, k represents a coefficient of a standard deviation of normal distribution (a relationship between a sigma level and defects per million opportunity) of the load−current changing curve and the current−time changing curve of the car, and o represents a variance of the load−current and the current−time changing curve of the car.

5. The method according to claim 4, wherein a value range of k is 1 to 6.

6. The method according to claim 1, wherein the car load sample is obtained through a cloud−interface loadmeter of the car, and the drive current sample is through a cloud-interface clip-on ammeter.

7. A device for improving elevator maintainability, comprising:
a car load sample configured for providing car load information;
a drive current sample at least comprising an input current detection module and an output current detection module, wherein the input current detection module is configured for detecting an input current of the car load sample and the output current detection module is used for detecting an output current of the car load sample;
a central processing unit respectively connected with the car load sample and the drive current sample; and
a sensor configured for feeding back an input current detected by the input current detection module to the central processing unit.

8. The device according to claim 7, wherein the car load sample is obtained through a cloud-interface loadmeter of the car, and the drive current sample is through a cloud-interface clip-on ammeter.
